(19) United States
(12) Patent Application Publication
(10) Pub. No.: US 2026/0328817 A1
(43) Pub. Date: Oct. 22, 2026

(54) Arrangement And Method For Detecting A Current Of A First Conductor Of A Circuit

(71) Applicant: Siemens Aktiengesellschaft, München (DE)

(72) Inventors: Jennifer Sirtl, Fürth (DE); Michael Lager, Herzogenaurach, Bayer (DE); Gopal Mondal, Erlangen (DE); Sebastian Nielebock, Forchheim (DE)

(73) Assignee: Siemens Aktiengesellschaft, München (DE)

(21) Appl. No.: 19/108,897

(22) PCT Filed: Aug. 29, 2023
(86) PCT No.: PCT/EP2023/073595

§ 371 Date: Mar. 5, 2025

(30) Foreign Application Priority Data
Sep. 6, 2022 (EP) 22194190.9

(51) Int. Cl. G01R 19/00

(52) U.S. Cl. CPC G01R 19/0092

(57) ABSTRACT

Various embodiments of the teachings herein include a method for detecting a current of a first conductor of a circuit at least partly mounted on a printed circuit board. An example includes: arranging two bodies around the conductor so loops are operated in the plane concentrically around the first current conductor; the bodies are conductively connected by a second current conductor forming a U profile perpendicular to the plane; operating the first body with a first input of a transimpedance amplifier formed by an operational amplifier and the second body with a second input of the transimpedance amplifier in connection so the transimpedance amplifier brings about a short circuit; wherein a short-circuit current flows from the transimpedance amplifier as input variable of the transimpedance amplifier through the first body, the second body, and the functionally connected second current conductor, and generates a voltage at an output of the transimpedance amplifier.

### CROSS-REFERENCE TO RELATED APPLICATIONS

This application is a U.S. National Stage Application of International Application No. PCT/EP2023/073595 filed Aug. 29, 2023, which designates the United States of America, and claims priority to EP Application No. 22194190.9 filed Sep. 6, 2022, the contents of which are hereby incorporated by reference in their entirety.

### TECHNICAL FIELD

The present disclosure relates to circuits. Various embodiments of the teachings herein include systems and/or methods for detecting a current of a first current conductor of a circuit which is in particular at least partly mounted on a printed circuit board.

### BACKGROUND

Methods and arrangements for detecting currents are known. These approaches generally differ in that they involve measuring methods based on different physical effects. Examples of this are measuring methods that use so-called shunt measurement, a magnetic field measurement, for example the so-called giant magnetoresistance, GMR, effect, measurement based on a Rogowski coil and measurement based on the power transformer approach.

However, the measuring methods and arrangements mentioned have the disadvantage that they are generally limited in terms of frequency due to various factors, for example due to core materials to be used, winding capacitances and/or compensation devices.

### SUMMARY

The teachings of the present disclosure include solutions which overcome the disadvantages of the prior art. In particular, the teachings specify methods and arrangements which enable a simple implementation, in particular for integration of the measuring method in a printed circuit board. For example, some embodiments of the teachings herein include a method for detecting a current of a first current conductor of a circuit which is in particular at least partly mounted on a printed circuit board, wherein a) a first body which conducts current which forms a closed loop in a plane and a second body which conducts current which forms a closed loop in a plane are placed around the conductor in such a way that the loops of the bodies formed are arranged and operated in the plane concentrically around the first current conductor which is placed at the geometric center thereof, which carries the current to be detected and which runs perpendicularly through the plane, wherein the bodies are shaped in such a way and/or are functionally connected to one another and operated in such a way that they are conductively connected by way of at least one second current conductor which forms in cross section a U profile perpendicular to the plane, wherein each of the two limbs of the U profile in cross section lie on the respective cross-sectional plane and the first limb of the U profile is connected to the first body via a first connecting point and the second limb of the U profile is connected to the second body via a second connecting point, in particular the first connecting point and the second connecting point of the U profile lie with the center on a straight line, b) the first body having a first input of a transimpedance amplifier which is formed in particular by an operational amplifier and the second body having a second input of the transimpedance amplifier are operated in connection in such a way that the transimpedance amplifier is able to bring about a short circuit, wherein a short-circuit current, which flows from the transimpedance amplifier as input variable of the transimpedance amplifier through the first body, the second body and the shaped and/or functionally connected at least one second current conductor in the event of a short circuit being brought about, generates a voltage at an output of the transimpedance amplifier.

In some embodiments, the first body and the second body are functionally connected and operated in such a way that each point of the first closed loop is connected to the parallel point of the second loop via a conductive connection, which forms a U profile in cross section, in such a way that a cross section circulating around the center always has a U profile such that the at least one second current conductor having the first body and the second body is in the form of a hollow body which forms a circulating U profile.

In some embodiments, the first body, the second body and/or the at least one second current conductor are operated at least partly as conductor tracks of a printed circuit board.

In some embodiments, the first current conductor, the at least one second current conductor and/or the functional connections are operated as so-called vertical interconnect access, via, connections through the printed circuit board.

In some embodiments, the first body, the second body and/or the at least one second current conductor is shaped and/or functionally connected in such a way that it is operated in inner layers of the printed circuit board.

In some embodiments, the voltage at the output of the transimpedance amplifier is supplied as input signal to a first module which performs an integration.

In some embodiments, the module is functionally connected to the transimpedance amplifier and operated in such a way that the first module acts as an integrator circuit.

In some embodiments, a second module is functionally connected to the transimpedance amplifier and operated in such a way that the second module acts as an analog-to-digital converter, wherein the analog value of the voltage at the output of the transimpedance amplifier is converted to a digital representation of the value of the voltage and functionally connected to a computation unit, which is configured in particular as a digital signaling processor, DSP, a so-called central programming unit, CPU, or a so-called application-specific integrated circuit, ASIC, and operated in such a way that the computation unit is used to carry out the integration.

As another example, some embodiments include an arrangement for detecting a current of a first current conductor of a circuit which is in particular at least partly mounted on a printed circuit board, wherein a) a first body which conducts current which forms a closed loop in a plane and a second body which conducts current which forms a closed loop in a plane are placed around the conductor in such a way that the loops of the bodies formed are arranged and operated in the plane concentrically, in particular annularly, around the first current conductor which is placed at the geometric center thereof, which carries the current to be detected and which runs perpendicularly through the plane, wherein the bodies are shaped in such a way and/or are functionally connected to one another and operated in such a way that they are conductively connected by way of at least one second current conductor which forms in cross section a U profile perpendicular to the plane, wherein each of the two limbs of the U profile in cross section lie on the respective cross-sectional plane and the first the of the U profile is connected to the first body via a first connecting point and the second limb of the U profile is connected to the second body via a second connecting point, in particular the first connecting point and the second connecting point of the U profile lie with the center on a straight line, b) the first body having a first input of a transimpedance amplifier which is formed in particular by an operational amplifier and the second body having a second input of the transimpedance amplifier are operated in connection in such a way that the transimpedance amplifier is able to bring about a short circuit, wherein a short-circuit current, which flows from the transimpedance amplifier as input variable of the transimpedance amplifier through the first body, the second body and the shaped and/or functionally connected at least one second current conductor in the event of a short circuit being brought about, generates a voltage at an output of the transimpedance amplifier.

In some embodiments, the first body and the second body are functionally connected and operated in such a way that each point of the first closed loop is connected to the parallel point of the second loop via a conductive connection, which forms a U profile in cross section, in such a way that a cross section circulating around the center always has a U profile such that the at least one second current conductor having the first body and the second body is in the form of a hollow body which forms a circulating U profile.

In some embodiments, the first body, the second body and/or the at least one second current conductor are operated at least partly as conductor tracks of a printed circuit board.

In some embodiments, the first current conductor, the at least one second current conductor and/or the functional connections are operated as so-called via, vertical interconnect access, connections through the printed circuit board.

In some embodiments, the first body, the second body and/or the at least one second current conductor is/are shaped and/or functionally connected in such a way that it/they is/are operated in inner layers of the printed circuit board.

In some embodiments, the voltage at the output of the transimpedance amplifier is applied as input signal to a first module which performs an integration.

In some embodiments, the first module is functionally connected to the transimpedance amplifier and configured in such a way that the first module acts as an integrator circuit.

In some embodiments, a second module is functionally connected to the transimpedance amplifier and operated in such a way that the second module acts as an analog-to-digital converter, wherein the analog value of the voltage at the output of the transimpedance amplifier is converted to a digital representation of the value of the voltage and functionally connected to a computation unit, which is configured in particular as a digital signaling processor, DSP, a so-called central programming unit, CPU, or a so-called application-specific integrated circuit, ASIC, and operated in such a way that the computation unit is used to carry out the integration.

### BRIEF DESCRIPTION OF THE DRAWINGS

Further advantages and details of the teachings herein are explained based on the exemplary embodiments illustrated in FIGS. 1 to 3. In the figures:

FIG. 1 schematically shows an example an arrangement having three windings as measurement value pickup incorporating teachings of the present disclosure;

FIG. 2 schematically shows another example arrangement incorporating teachings of the present disclosure and having a cylindrical molded part with a U cross section as measurement value pickup; and

FIG. 3 schematically shows an example transimpedance amplifier incorporating teachings of the present disclosure.

### DETAILED DESCRIPTION

Some examples of the teachings herein include a method for detecting a current of a first current conductor of a circuit which is in particular at least partly mounted on a printed circuit board, a first body which conducts current which forms a closed loop in a plane and a second body which conducts current which forms a closed loop in a plane are placed around the first current conductor in such a way that the loops of the bodies formed are arranged and operated in the plane concentrically, in particular annularly, around the first current conductor which is placed at the geometric center thereof, which carries the current to be detected and which runs perpendicularly through the plane, wherein the bodies are shaped in such a way and/or are functionally connected to one another and operated in such a way that they are conductively connected by way of at least one second current conductor which forms in cross section a U profile perpendicular to the plane, wherein the two limbs of the U profile in cross section lie on the respective cross-sectional plane and the first limb of the U profile is connected to the first body via a first connecting point and the second limb of the U profile is connected to the second body via a second connecting point, in particular the first connecting point and the second connecting point of the U profile in each case lie with the center on a straight line; furthermore, the first body having a first input of a transimpedance amplifier which is formed in particular by an operational amplifier and the second body having a second input of the transimpedance amplifier are operated in connection in such a way that the transimpedance amplifier is able to bring about a short circuit, wherein a short-circuit current, which flows from the transimpedance amplifier as input variable of the transimpedance amplifier through the first body, the second body and the shaped and/or functionally connected at least one second current conductor in the event of a short circuit being brought about, generates a voltage at an output of the transimpedance amplifier (transimpedance transducer).

As a result of the fact that the first and the second body and the functionally connected and/or shaped at least one second current conductor are functionally connected and operated in an inventive manner, a current is induced in the resulting AC loop when current flows through the first current conductor and because the transimpedance amplifier is functionally connected and operated in such a way that it produces a short circuit in this case using the first and second body and the at least one second current conductor. Induction results since the alternating current of the first current conductor generates a magnetic field H which in turn pervades the mesh of the second current conductor perpendicularly. The value of the current changes in accordance with a change in the value of the current flowing through the first current conductor and, due to the procedure in accordance with the method, is applied to the transimpedance amplifier such that a voltage which is proportional to the change in short-circuit current is applied to the output of said transimpedance amplifier. The evaluation of this voltage can thus be used to detect the change in current.

The methods described herein make it possible in particular to implement current detection methods on printed circuit boards, other than those measuring based on the Rogowski coil approach known from the prior art, which are based on sensors since the procedure according to the invention generates a strong signal so that very easily evaluable signals which are proportional to the change in current can be produced even using few second current conductors, in particular through operation of the transimpedance amplifier. In contrast to attempts known from the prior art for implementing the Rogowski coil approach, the detection of a current thus does not require from 100 up to a multiple of 100 loops but instead only the few loops resulting from the U shape by way of the second current conductor. The methods thus significantly reduce the very large number of holes in the printed circuit boards that would otherwise be necessary according to the prior art, additionally reduces inter alia the outlay and ensures significantly more degrees of freedom in the design of the printed circuit board.

In addition, the procedure enables electrically isolated current detection. All of this is provided by an operational amplifier, in particular in an implementation of the transimpedance amplifier, such that this results in a very good implementation variant of the possible implementation variants.

The elements which are functionally connected and operated in accordance with the invention additionally enable flexible adaptation to the dimension of the current expected in the first current conductor, that is to say the current to be detected.

Although an alignment of the connecting points on the conductor as a central point is a possible design option, for example a conceivable design option if there is a desire for symmetry, this is not necessary for the current detection since the signal produced for the current detection is provided by the surface of the measurement sensor through which the H field of the change in current to be detected passes.

These advantages also apply to the methods in which the first body and the second body are functionally connected and operated in such a way that each point of the first closed loop is connected to the parallel point of the second loop via a conductive connection, which forms a U profile in cross section, in such a way that a cross section circulating around the center always has a U profile such that the at least one second current conductor having the first body and the second body is in the form of a hollow body which forms a circulating U profile.

This solution thus shapes the at least one second current conductor from the first and second body to form a three-dimensional overall structure. These bodies could also be considered the result of an infinitely large number of second current conductors melted together and radially arranged around the first current conductor being joined together, said second current conductors fully enclosing the first current conductor and in which the magnetic field generated by the alternating current of the first current conductor is penetrated on a greater scale. It can also be considered as a single shaped second current conductor which, in comparison to a second current conductor provided by a single winding, is penetrated differently by the magnetic field and already for this reason alone exhibits other properties that can meet corresponding requirements of an implementation. Further advantages of this arrangement may be inter alia a greater robustness, complete absence of bores in printed circuit boards and/or alternative design options.

In some embodiments, the first body, the second body and/or the at least one second current conductor are operated at least partly as conductor tracks of a printed circuit board. This can reduce the outlay for providing the method according to the invention since at least some of the connections and functional units required are already produced during manufacture of the conductor tracks structure of the printed circuit board and at most few elements have to be assembled.

In some embodiments, the first current conductor, the at least one second current conductor and/or the functional connections are operated as so-called vertical interconnect access, via, connections through the printed circuit board. This makes it possible to also produce the horizontal elements required for the current detection method as early as the manufacture of the printed circuit board structure, such that population outlay is reduced even further.

In some embodiments, the first body, the second body and/or the at least one second current conductor is shaped and/or functionally connected in such a way that it is operated in inner layers of the printed circuit board. This procedure firstly utilizes one of the potentials of the methods, which is that of improved minimization possibilities, and permits the methods to be operated in an at least partly hidden manner or to be operated such that for example there is still space for shields on the so-called outer layers or additional degrees of freedom for conductor track structures are provided on the outer layers, for example the current branch whose current is to be detected.

In some embodiments, the voltage at the output of the transimpedance amplifier is supplied as input signal to a first module which performs an integration, the value of the detected current can advantageously be determined and not just the change in said current. As a result thereof, the method can be operated depending on a desired variable to be measured and said variable can be made detectable.

In some embodiments, the method may be configured depending on the requirement for the circuit or in principle depending on the desired design such that the first module is functionally connected to the transimpedance amplifier and operated in such a way that the module acts as an integrator circuit. An integrator circuit is a simple analog configuration for converting the detected change in current to a current value which is brought about by integration.

If there is a desire to save on components and/or to retain the digitally processable signals as the result of the method according to the invention for current detection, the method according to the invention can be configured in such a way that a second module is functionally connected to the transimpedance amplifier and operated in such a that the second module acts as an analog-to-digital converter, wherein the analog value of the voltage at the output of the transimpedance amplifier is converted to a digital representation of the value of the voltage and functionally connected to a computation unit, which is configured in particular as a digital signaling processor, DSP, a so-called central programming unit, CPU, or a so-called application-specific integrated circuit, ASIC, and operated in such a way that the computation unit is used to carry out the integration.

As another example, some embodiments of the teachings herein include an arrangement for detecting a current of a first current conductor of a circuit which is in particular at least partly mounted on a printed circuit board, a first body which conducts current which forms a closed loop in a plane and a second body which conducts current which forms a closed loop in a plane are placed around the first current conductor in such a way that the loops of the bodies formed are arranged and operated in the plane concentrically, in particular annularly, around the first current conductor which is placed at the geometric center thereof, which carries the current to be detected and which runs perpendicularly through the plane, wherein the bodies are shaped in such a way and/or are functionally connected to one another and operated in such a way that they are conductively connected by way of at least one second current conductor which forms in cross section a U profile perpendicular to the plane, wherein the two limbs of the U profile in cross section lie on the respective cross-sectional plane and the first limb of the U profile is connected to the first body via a first connecting point and the second limb of the U profile is connected to the second body via a second connecting point, in particular the first connecting point and the second connecting point of the U profile in each case lie with the center on a straight line; furthermore, the first body having a first input of a transimpedance amplifier which is formed in particular by an operational amplifier and the second body having a second input of the transimpedance amplifier are operated in connection in such a way that the transimpedance amplifier is able to bring about a short circuit, wherein a short-circuit current, which flows from the transimpedance amplifier as input variable of the transimpedance amplifier through the first body, the second body and the shaped and/or functionally connected at least one second current conductor in the event of a short circuit being brought about, generates a voltage at an output of the transimpedance amplifier.

The advantages and configurations and developments cited in relation to the methods above can be applied analogously to the arrangements and also lie in the fact that they allow the method to be carried out by way of their implementation. The same also applies to the configurations and developments of the arrangements which accordingly correspond to the configurations and developments of the methods. The advantages can also be transferred mutatis mutandis in this case such that, provided no other advantages are specified, they have at least said advantages and they each also at least additionally provide the advantage of making it possible to carry out the accordingly corresponding configurations and developments of the methods.

In some embodiments, the first body and the second body are functionally connected and operated in such a way that each point of the first closed loop is connected to the parallel point of the second loop via a conductive connection, which forms a U profile in cross section, in such a way that a cross section circulating around the center always has a U profile such that the at least one second current conductor having the first body and the second body is in the form of a hollow body which forms a circulating U profile. This induces the short-circuit current in a single-piece molded part which is proportional to the change in current in the conductor. Such a single-piece molded part has the advantage, inter alia, that it reduces the outlay when populating a circuit with the arrangement according to the invention for detecting a current, for example.

In some embodiments, the first body, the second body and/or the at least one second current conductor are operated at least partly as conductor tracks of a printed circuit board. This represents or enables integration of the arrangement on a printed circuit board which is provided with for a loop to be measured.

In some embodiments, the first current conductor, the at least one second current conductor and/or the functional connections are operated as so-called vertical interconnect access, via, connections through the printed circuit board; this also supports the integration on the printed circuit board and utilizes the thickness of the printed circuit board for realizing the limbs of the second current conductor, which are also able to be produced almost exclusively when the conductor track structure of the printed circuit board is applied.

In some embodiments, the first body, the second body and/or the at least one second current conductor is/are shaped and/or functionally connected in such a way that it/they is/are operated in inner layers of the printed circuit board.

In some embodiments, the voltage at the output of the transimpedance amplifier is applied as input signal to a module which performs an integration, the signal produced by the method representing the absolute value of a voltage proportional to the change in current is converted to another signal which is also a voltage but is proportional to the value of the current actually currently flowing through the conductor. As a result, this goes beyond purely detecting the presence of current in the first current conductor based on changes to detecting-indirectly through the proportionality-the value of the actual current which is then also available for evaluation, changing state and/or control purposes or other actions which can be derived based on the current.

In some embodiments, the first module is functionally connected to the transimpedance amplifier and configured in such a way that the first module acts as an integrator circuit. This will generally constitute a solution which is able to output the signal provided as an analog signal as an analog signal too, such that when designing a circuit which uses the arrangement according to the invention and which requires an analog signal for further processing, this can be provided.

In some embodiments, a second module is functionally connected to the transimpedance amplifier and operated in such a way that the second module acts as an analog-to-digital converter, wherein the analog value of the voltage at the output of the transimpedance amplifier is converted to a digital representation of the value of the voltage and functionally connected to a computation unit, which is configured in particular as a digital signaling processor, DSP, a so-called central programming unit, CPU, or a so-called application-specific integrated circuit, ASIC, and operated in such a way that the computation unit is used to carry out the integration. As a result, when designing a circuit which uses the arrangement according to the invention and which requires a digital signal for further processing, this can also be provided. In other words, the sensor/transimpedance amplifier combination without an integrative component can thus directly provide the analog current change signal to an analog input of a computation unit, for example an available DSP or a CPU, and the integration of the signal for the current signal can be produced digitally. In addition to the advantage of reduced circuitry outlay, it is possible to prevent the integration result from drifting due to the digital integration by cyclically or strategically zeroing the integrator. Another advantage is a significantly higher dynamic range provided by the digitization or a high resolution resulting from the integration according to the invention.

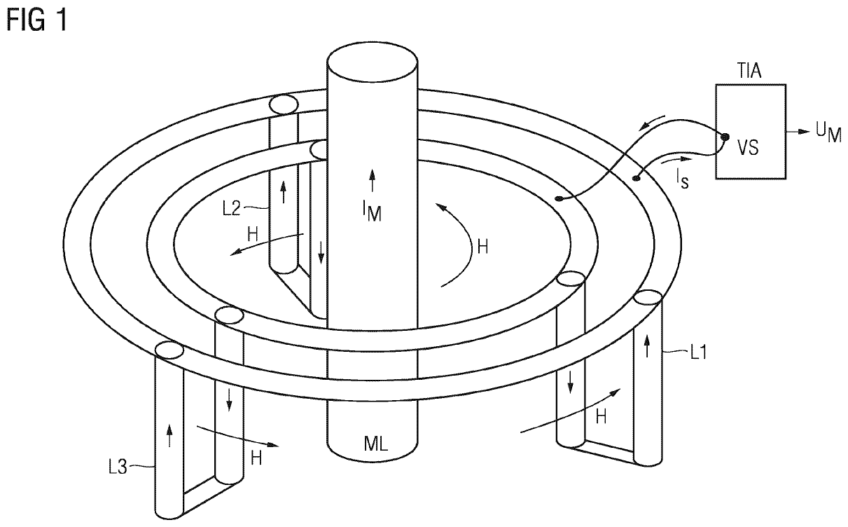

The embodiments depicted in FIG. 1 to FIG. 3 are merely example embodiments of the teachings herein and not an exhaustive illustration thereof. In particular, the exemplary embodiments below merely show realization options for how in particular such realizations of the teaching according to the invention might look, since it is impossible and also not practical or necessary for comprehension of the invention to cite all of these realization options.

Moreover, in particular a person skilled in the art, with knowledge of the arrangement claim/arrangement claims and/or method claim/method claims, is of course aware of all routine possibilities for realizing the invention in the prior art, and so there is no need in particular for independent disclosure in the description. In the exemplary embodiments, the components described each represent individual features which can be considered independently of each other, each also develop independently of each other and can therefore also be regarded, individually or in a combination other than the one shown, as a component part. Furthermore, the exemplary embodiments described can also be supplemented with further features of the already described features. Identical reference signs have the same meaning in the various figures.

The exemplary embodiment shown in FIG. 1 schematically illustrates a configuration variant of the arrangement incorporating teachings of the present disclosure and this is explained in more detail below together with the function thereof and thus an exemplary embodiment of the method as well.

The exemplary embodiment illustrated in FIG. 1 is based in principle, in contrast to the Rogowski measuring method, on a short-circuit current measurement which in principle has a lower inductance and lower parasitic capacitances owing to the quicker removal of charge carriers and owing to the significantly lower number of sensor windings. This results in the fact that the circuit has a significantly better cut-off frequency and a lower capacitive coupling (dU/dt) with respect to the measuring circuit. Said circuit is therefore suitable in particular for resonant circuits, among others. These and other potential advantages will become clearer with the following description of the exemplary embodiments.

FIG. 1 shows a configuration in which the at least one second current conductor may be designed in principle as one or even more windings L₁ . . . Lₙ which are formed of a first current conductor L1, a second current conductor L2 and a third current conductor L3. As can be seen, these current conductors form U-shaped windings which are arranged around two electrically conductive first bodies K1 and second bodies K2, which are likewise formed around the current conductors ML to be measured and are in the form of two concentric circuits and are connected thereto.

The illustration also shows that the current conductors L1 . . . L3 each electrically conductively connect the first body K1 and the second body K2 and are thus positioned, in particular evenly distributed, in a manner connected in parallel with and concentrically around the first current conductor ML to be measured.

FIG. 1 also schematically indicates that the limbs of the three windings L1 . . . L3 run perpendicularly from the concentrically arranged first body K1 and a second body K2, which are placed on a first outer layer of a printed circuit board, not illustrated in FIG. 1, to the opposite second outer layer, likewise not illustrated, where short conductor track pieces connect the limbs which are in the form of vertical vias and thus form the U shape. The windings may thus be realized as a combination of vias and conductor tracks in a printed circuit board, as illustrated in a highly simplified manner in FIG. 1.

In the exemplary embodiment shown, the current conductor ML to be measured may be fed through a hole in the printed circuit board or may also be in the form of a conductor track having a via arrangement. An alternating current IM to be detected flows at least temporarily in the first current conductor ML to be measured. Said alternating current in turn generates a magnetic alternating field H which runs annularly around the current conductor ML to be measured and is indicated in FIG. 1 by some arrows symbolizing the magnetic field. Said magnetic field H pervades the second current conductors L1 . . . L3 formed as windings in this exemplary embodiment. As a result, a short-circuit current IS flows, if the windings are short-circuited via a transimpedance amplifier TIA according to the method according to the invention. The windings L1 . . . L3 thus constitute measurement value pickups. The short circuit is thus realized according to the method according to the invention by way of a transimpedance amplifier TIA provided according to an exemplary embodiment of the arrangement according to the invention.

The loop induced by the magnetic alternating field can thus only be closed via the transimpedance amplifier. Said transimpedance amplifier transforms the short-circuit current into a measurement voltage. The measurement voltage is proportional to the change in current dI/dt. If the absolute current is required, the measurement signal is integrated by an integrator in accordance with one development of the arrangement, which results in a measurement signal proportional to the current.

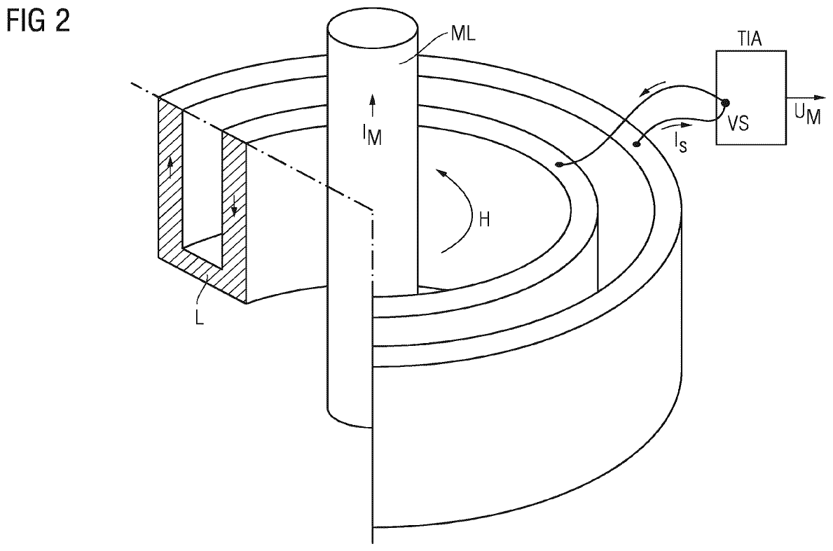

As an alternative to discrete windings L1 . . . 3 connected in parallel with one another, a construction as is illustrated in FIG. 2 as an exemplary embodiment of the arrangement is also conceivable. In this exemplary embodiment, the measurement value pickup consists of a conductive, U-shaped molded part L which encloses the current conductor ML to be measured by the current IM to be measured. It can be seen in the sectional illustration of FIG. 2 that the molded part L is a cylindrically shaped body which has a cylindrical recess running about the axis of symmetry of the body, that is to say forms a kind of tube, the edge of which has a U cross section running about the axis of symmetry. The ratio of the diameter of the tube to the length thereof is generally configured in this case such that the diameter is greater than the length of the tube, that is to say the tube equates to a disc with a circular recess.

At one end of the tube, the plan view thus shows two concentric circles corresponding to the first body K1 and the second body K2. On the opposite end of the tube, in contrast, the plan view shows a circle running about the axis of symmetry resulting from a base that forms the limbs of a U. The molded part L could thus also be considered as an infinite number of fused U-shaped windings.

In this example, too, a transimpedance amplifier TIA is used for converting the short-circuit current IS to a voltage which is proportional to the change in current. To this end, a first input of the transimpedance amplifier TIA is connected to one of the circles of the tube and analogous to the first body K1 and a second input of the transimpedance amplifier TIA is conductively connected to the other circuit which is analogous to the second body K2.

In this example, too, an integrator can convert the output signal from the transimpedance amplifier TIA to a voltage which is proportional to the measuring change in current of the measurement current IM.

The solution shown having a measurement value pickup shaped as a U molded part L may be advantageous for example if a measurement value pickup with which a circuit is populated is required to realize the methods.

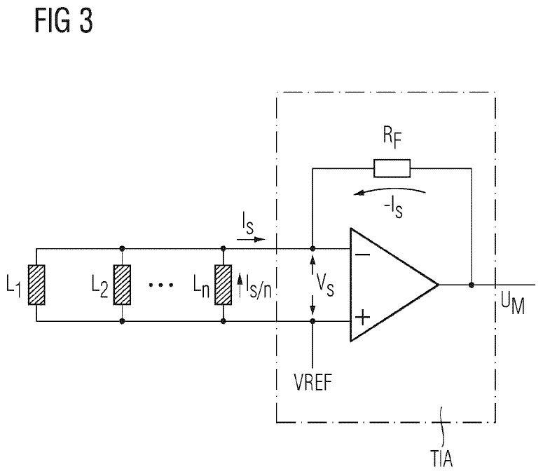

FIG. 3 schematically illustrates a basic structure of an exemplary embodiment of a transimpedance amplifier TIA incorporating teachings of the present disclosure. The windings which are possible are in this example switching symbols for coils which may be realized according to the invention in each case by a loop/winding. The coils L₁ . . . Lₙ illustrated in FIG. 3 thus represent a number of n loops which are illustrated in parallel connection in FIG. 1 and the two terminals of which are connected to each one of the two inputs of the transimpedance amplifier TIA, thus also in parallel connection, said transimpedance amplifier being in the form of an operational amplifier according to the exemplary embodiment, the − and + input of which is used as an input of the transimpedance amplifier TIA and which is also wired such that a feedback resistor RF leads from the output of the operational amplifier to the − input of the operational amplifier.

In this case, the feedback resistor RF impresses a short-circuit current Iₛ in the loop to the windings L₁ . . . Lₙ, said short-circuit current being divided in accordance with Kirchhoff's law across the individual windings according to the number n of windings. The sum of the individual currents Iₛ/n in the current branch corresponds in terms of absolute value to the impressed short-circuit current Is which was produced by the magnetic alternating field H field. The fact that the overall short-circuit current is formed by the sum of any branch currents forming and corresponds to the impressed short-circuit current Iₛ, which passes to the input of the transimpedance amplifier, thus always applies to the exemplary embodiments shown in FIG. 1 and FIG. 2 as well, where the branch currents are illustrated as arrows in the conductors. Since the −/+ inputs of the operational amplifier have the same potential as a result, a virtual short circuit VS may be discussed here. However, from the view of the windings, the windings L₁ . . . Lₙ are thus operated in a real short circuit.

The advantages of the teachings herein with respect to the solutions known from the prior art consist, inter alia, in that the measuring method can be easily integrated into a printed circuit board since only few via conductor tracks are required to realize the sensor, the measurement value pickup. In test setups, 3 conductor loops were sufficient to realize a measurement value pickup, wherein the conductor loops L₁ . . . Lₙ are also very easy to implement owing to the parallel connection. As a result, inter alia, the arrangement and the method have a significant advantage compared to implementations tested in the prior art for integrating a Rogowski coil in a printed circuit board.

According to approaches known from the prior art having a Rogowski coil, each conductor loop delivers only signals in the single-digit millivolt range. Therefore, an arrangement of 100 to several hundred loops is required according to the prior art, which results in large, perforated structures on the printed circuit board. In contrast thereto, the solution according to the invention delivers a relatively powerful current signal, in particular in comparison with the prior art, which can easily be transformed into a voltage signal by a transimpedance amplifier TIA and evaluated.

The powerful signal additionally also makes it possible to use small loop constructions in the inner layers of a printed circuit board in order for example to implement a shield for the coupling capacitance or the current branch for the current IM to be measured. The integrator which can be used when required may conventionally be provided via an essentially analog circuit or, according to an A/D conversion, digitally as well by means of a computation unit (DSP/CPU). This may be particularly advantageous if such a computation unit is already part of the circuit measured and thus performs only an additional function. This saves space and removes additional component costs.

Furthermore, the branch to be measured may be electrically isolated from the measurement branch. This overcomes the disadvantages for example which result in current detection by means of shunt measurement. Compared to the approaches for current detection known from the prior art which are based on power transformers, magnetic field sensors and approaches using Rogowski coils known from the prior art, the result is another advantage that the measuring principle does not involve frequency-limiting factors such as core materials, winding capacitances, series inductance and limitations due to compensation devices.

Measurements with the pickup configuration for testing show that the solutions described herein may have a resonant frequency in the medium two-digit MHz range. In contrast to commercially available components such as shunts, magnetic sensors, and power transformers, the measuring device may also be flexibly adapted to the current IM to be measured. In particular when integrating the invention on a printed circuit board, there are no or hardly any costs for the sensor because a printed circuit board is provided anyway. Particularly when using via connections and conductor tracks for the windings, the only costs are the transimpedance amplifier and/or the integrator.

What is claimed is:

1. A method for detecting a current of a first conductor of a circuit at least partly mounted on a printed circuit board, the method comprising:
arranging a first body conducting current to form a closed loop in a plane and a second body conducting current to form a closed loop in the plane around the conductor so loops of the bodies formed are arranged and operated in the plane concentrically around the first current conductor at the geometric center thereof, carrying the current to be detected and running perpendicularly through the plane;
wherein the bodies are functionally connected to one another and conductively connected by a second current conductor which forms in cross section a U profile perpendicular to the plane, wherein each of two limbs of the U profile in cross section lie on a respective cross-sectional plane and the first limb is connected to the first body via a first connecting point and the second limb is connected to the second body via a second connecting point;
operating the first body with a first input of a transimpedance amplifier formed by an operational amplifier and the second body with a second input of the transimpedance amplifier in connection so the transimpedance amplifier brings about a short circuit;
wherein a short-circuit current flows from the transimpedance amplifier as input variable of the transimpedance amplifier through the first body, the second body, and the functionally connected second current conductor and generates a voltage at an output of the transimpedance amplifier.

2. The method as claimed in claim 1, wherein the first body and the second body are functionally connected and operated so each point of the first closed loop is connected to the parallel point of the second loop via a conductive connection forming a U profile in cross section, so a cross section circulating around the center has a U profile so the second current conductor having the first body and the second body comprises a hollow body which forms a circulating U profile.

3. The method as claimed in claim 1, wherein the first body, the second body, and/or the second current conductor are operated at least partly as conductor tracks of a printed circuit board.

4. The method as claimed in claim 3, wherein the first current conductor, the second current conductor, and/or the functional connections are operated as so-called vertical interconnect access connections through the printed circuit board.

5. The method as claimed in claim 3, where in the first body, the second body and/or the second current conductor is shaped and/or functionally connected to inner layers of the printed circuit board.

6. The method as claimed in claim 1, further comprising supplying the voltage from the output of the transimpedance amplifier as an input signal to a first module to perform an integration.

7. The method as claimed in claim 6, wherein the module is functionally connected to the transimpedance amplifier to act as an integrator circuit.

8. The method as claimed in claim 1, further comprising operating a second module functionally connected to the transimpedance amplifier so the second module acts as an analog-to-digital converter;
wherein the analog value of the voltage at the output of the transimpedance amplifier is converted to a digital representation of the value of the voltage and functionally connected to a computation unit comprising: a digital signaling processor, a central programming unit, or a application-specific integrated circuit, and operated so the computation unit carries out the integration.

9. An arrangement for detecting a current of a first current conductor of a circuit at least partly mounted on a printed circuit board, the arrangement comprising:
a first body conducting current forming a closed loop in a plane;
a second body conducting current forming a closed loop in the plane;
wherein the first body and the second body are arranged around the conductor so loops of the first body and the second body are arranged and operated in the plane concentrically around the first current conductor at the geometric center thereof;
where in the first current conductor carries the current to be detected and which runs perpendicularly through the plane;
wherein the first body and the second body are shaped and/or functionally connected to one another and operated in conductive connection using a second current conductor forming in cross section a U profile perpendicular to the plane;
wherein each of the two limbs of the U profile in cross section lies on a respective cross-sectional plane and the first limb of the U profile is connected to the first body via a first connecting point and the second limb of the U profile is connected to the second body via a second connecting point;
delivering to the first body a first input of a transimpedance amplifier formed by an operational amplifier; and
delivering to the second body a second input of the transimpedance amplifier so the transimpedance amplifier brings about a short circuit;
wherein a short-circuit current flows from the transimpedance amplifier as input variable of the transimpedance amplifier through the first body, the second body, and the shaped and/or functionally connected second current conductor and generates a voltage at an output of the transimpedance amplifier.

10. The arrangement as claimed in claim 9, wherein the first body and the second body are functionally connected and operated so each point of the first closed loop is connected to the parallel point of the second loop via a conductive connection, which forms a U profile in cross section, in such a way that a cross section circulating around the center always has a U profile such that the at least one second current conductor having the first body and the second body is in the form of a hollow body which forms a circulating U profile.

11. The arrangement as claimed in claim 9, wherein the first body, the second body, and/or the at least one second current conductor comprises conductor tracks of a printed circuit board.

12. The arrangement as claimed in claim 11, wherein the first current conductor, the second current conductor, and/or the functional connections are operated as vertical interconnect access connections through the printed circuit board.

13. The arrangement as claimed in claim 11, wherein the first body, the second body, and/or the second current conductor is shaped and/or functionally connected they are operated in inner layers of the printed circuit board.

14. The arrangement as claimed in claim 9, wherein
the voltage at the output of the transimpedance amplifier is applied as input signal to a first module to perform an integration.

15. The arrangement as claimed in claim 14, wherein the first module is functionally connected to the transimpedance amplifier to act as an integrator circuit.

16. The arrangement as claimed in claim 9, wherein a second module is functionally connected to the transimpedance amplifier and operated in such a way that the second module acts as an analog-to-digital converter, wherein the analog value of the voltage at the output of the transimpedance amplifier is converted to a digital representation of the value of the voltage and functionally connected to a computation unit comprising at least one of: a digital signaling processor, a central programming unity, or a application-specific integrated circuit, and operated in such a way that the computation unit is used to carry out the integration.
